(19) United States
(12) Patent Application Publication
(10) Pub. No.: US 2026/0136962 A1
(43) Pub. Date: May 14, 2026

(54) In-Situ Polymerization of Monomers on the Walls of Vias

(71) Applicant: Intel Corporation, Santa Clara, CA (US)

(72) Inventors: Seyyed Yahya MOUSAVI, Chandler, AZ (US); Minglu LIU, Chandler, AZ (US); Gang DUAN, Chandler, AZ (US); Mahdi MOHAMMADIGHALENI, Phoenix, AZ (US); Srinivas PIETAMBARAM, Chandler, AZ (US)

(21) Appl. No.: 18/946,972

(22) Filed: Nov. 14, 2024

(51) Int. Cl. H01L 23/498; H01L 21/48; H05K 1/11

(52) U.S. Cl. CPC H10W 70/635; H05K 1/115; H10W 70/095; H05K 2201/09563

(57) ABSTRACT

The present disclosure is directed to a device having a coating or liner of a polymer material that may significantly improve the mechanical performance and stability of through hole via interconnects, such as through glass vias interconnects, by damping the stresses from the expansion of copper used as a conductive material. The present lining method for the through hole vias uses selected polymers that have a low-viscosity and may be capable of in-situ polymerization, i.e., curing, after being placed in the through hole vias.

### BACKGROUND

As semiconductor technology advances, the need to improve performance and lower costs for integrated circuit design and fabrication are constant challenges. It is becoming more difficult and costly to realize high-volume manufacturing for semiconductors as transistors continue to shrink in size. Cost savings may be potentially realized by building more efficient structures and using materials that improve power performance.

In terms of dimensional and performance stability, silicon and glass are better suited for fine-pitch interconnects with high I/O density than organic substrates. However, as a semiconductor interconnect structure, silicon may require the deposition of dielectric layers, which raises production costs. On the other hand, as an insulating material, glass has become an attractive support material for advanced manufacturing and packaging due to its adjustable coefficient of thermal expansion (CTE), excellent surface flatness, high resistivity, and low cost. Therefore, glass has emerged as the material of choice in recent years for a new generation of semiconductor devices.

It is common to use through-glass-vias (TGVs) and microvias as the interconnects between layers in high-density interconnect substrates and printed circuit boards (PCBs) to accommodate the high input/output (I/O) density of advanced packages. The use of three-dimensional (3D) interconnects with TGV technology has wide applicability in radio frequency (RF) devices, optoelectronic systems, and multi-layer glass substrates. However, the conductive materials, such as copper (Cu), used to form a TGV may expand/shrink inside the through hole vias causing stresses on the glass substrate, which may lead to their failure. For example, a TGV-Cu structure may have induced-stress inside the TGV after undergoing high-temperature processes or reliability evaluations, which leads to the glass cracking due to a mismatch between the different CTEs of the materials. It is therefore important to have connectivity solutions that are able to improve a TGV's structure for advanced packages and improve the mechanical performance/stability of the through hole via connections.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a through hole via interconnect according to an aspect of the present disclosure;

FIGS. 2A through 2D show exemplary representations of a formation of polymer linings for through hole vias according to an aspect of the present disclosure;

FIG. 3 shows a simplified flow diagram for an exemplary method according to an aspect of the present disclosure;

FIGS. 4A through 4E show exemplary representations of another formation of polymer linings for through hole vias according to an aspect of the present disclosure; and

FIG. 5 shows a simplified flow diagram for another exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present device having a coating or liner of a polymer material that significantly improves the mechanical performance and stability of through hole via interconnects, such as through glass vias interconnects, by damping the stresses from the expansion/shrinkage of copper used as a conductive material. The present lining method for the through hole vias uses selected polymers that have a low viscosity and may be capable of in-situ polymerization, i.e., curing/polymerizing, after being placed in the through hole vias.

In an aspect, the present polymer lining includes monomers that effectively coat the vias may have a low modules, e.g., in a range of approximately one to four gigapascal (i.e., 1 to 4 GPa), and provide high toughness. In another aspect, the low modules may be in a range of approximately one-tenth to ten gigapascal (i.e., 0.1 to 10 GPa). In particular, selected monomers may have (i) a low viscosity (i.e., close to being water-like) with very low surface tension that may easily flow inside the through hole vias, (ii) a good interaction with glass to leave a thin layer/liner on the typical surface roughness produced with the formation of through hole vias, (iii) a fast polymerization rate using ultraviolet (UV) energy or heat or any other cure/polymerization accelerating procedures, and (iv) long chain polymer structures with little or no crosslinking for certain methods disclosed herein.

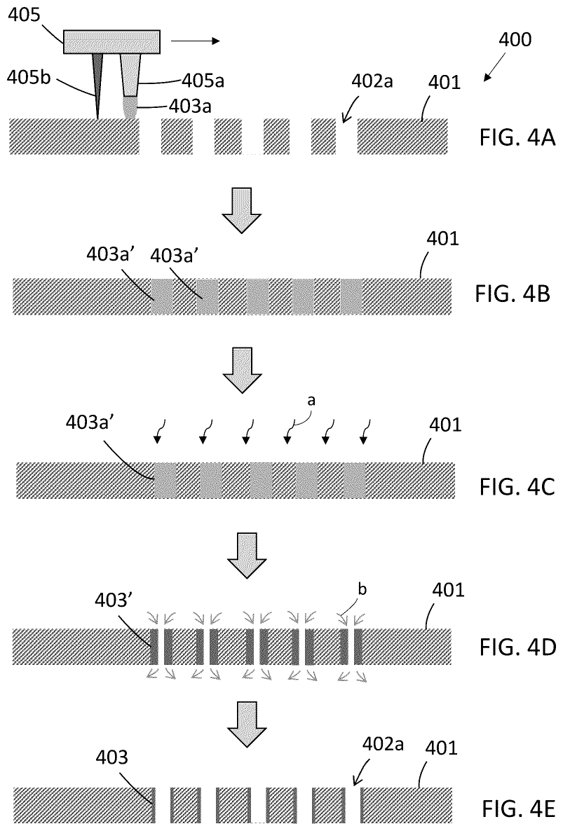

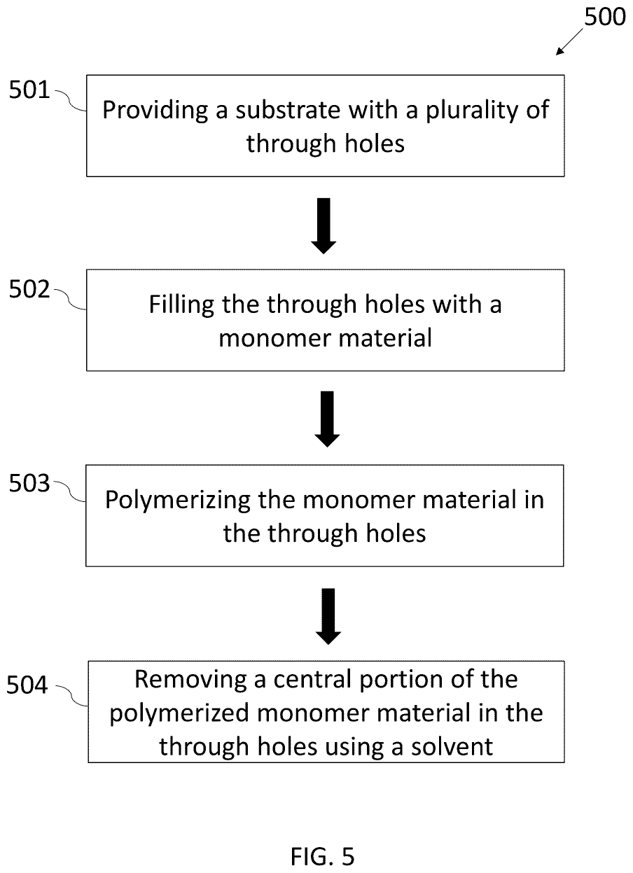

According to the present disclosure, the present monomers may be selected to enable fast polymerization in-situ, i.e., after placement in the through hole vias, using heat or ultraviolet energy. For example, acrylate-based monomers may be used, such as methacrylic acid, hydroxyethyl acrylate, etc., and uncured epoxy-based monomers may be used, such as glycidyl methacrylate, glycerol diglycidyl ether, triglycidylamine,1,2-propanediol diglycidyl ether, etc., which are only cured by heat or UV energy. The polymerized monomers should have little or no crosslinking for the methods shown in FIGS. 4 and 5 below.

In an aspect, for example, low-viscosity primary and/or secondary amine-based hardeners (i.e., curing agents) may be used in combination with the epoxy-based monomer, including acyclic-aliphatic amines such as diethylenetriamine, triethylenetetramine, dimethylaminopropylamine, diethylamino-propylamine, hexanediamine, as well as other cycloaliphatic amines. In addition, for example, carboxylic anhydrides may be used as curing agents such as phthalic anhydride, tetrahydrophthalic anhydride, methyltetrahydrophthalic anhydride, hexahydrophthalic anhydride, nadic methyl anhydride, and chlorendic anhydride. It may be possible to use hydroxyl based curing agents as well.

In an aspect, for example, cationic catalysts may be used in combination with the epoxy-based monomer, such as Lewis acids, inorganic salts of Al(III), B(III), Be(II) , Fe(III) , Sb(V) and Zn(II) , aryldiazonium salts, diaryliodonium salts, triarylsulfonium salts, onium salts of group VI elements including salts of positively charged sulfur, and dialkylphenacyl sulfonium salts. The cationic polymerization of epoxy resins are also catalyzed by inorganic acids such as perchloric acid, phosphoric acid, and tetrafluoroboric acid.

In an aspect, for example, anionic catalysts may be used in combination with the epoxy-based monomer, such as tertiary amine salts (e.g., tris(dimethylaminomethyl)phenol and tris(dimethylaminomethyl)phenol tri(2-ethylhexanoate), imidazoles (e.g., 2-methylimidazole, 2-ethyl-4-methyl-imidazole, and 2-phenylimidazole), cyclic amidines (e.g., 2-phenylimidazoline), substituted ureas (e.g., 3-phenyl-1,1-dimethyl urea and 1,1′-(4 methyl-m-phenylene) bis(3,3 dimethyl urea)), and quaternary phosphonium salts (e.g., ethyl triphenyl phosphonium iodide). Strong bases such as potassium hydroxide and sodium hydroxide may also be used as catalysts for anionic polymerization of epoxy resins.

In an aspect, fillers may be used in combination with the epoxy-based monomers, such as silicon dioxide, silicon, and other fillers, including conductive and non-conductive fillers.

The present disclosure provides a device including a substrate with a plurality of through hole vias disposed in the substrate and each through hole via has a sidewall, a conductive material filling the plurality of through hole vias, and a polymer lining disposed between the sidewall and the conductive material in each through hole via. In an aspect, the polymer lining is made of a polymerized monomer material that may include acrylate-based monomers and low-viscosity epoxy-based monomers and have a low modulus of elasticity in a range of approximately one to four gigapascal.

The present disclosure is also directed to a method that includes providing a substrate with a plurality of through hole vias disposed in the substrate, disposing a monomer material in the plurality of through hole vias, curing the monomer material, and forming a polymer lining. Thereafter, the method includes depositing a conductive material in the plurality of through hole vias to form a plurality of interconnects through the substrate.

In an aspect, the method further includes depositing the monomer material to (i) form coatings on sidewalls of the plurality of through hole vias or (ii) entirely fill the plurality of through hole and thereafter remove a central portion of the polymerized material filling the plurality of through hole after polymerization. A non-crosslinking polymer should be used when the through holes are filled with the polymerized material so that the central portion is able to be removed. The polymerization of the monomer material may be performed using ultraviolet energy or heat, catalytic polymerization, or any other polymerization method. In another aspect of the method, as shown in FIG. 4A though 4E, removing the central portion of the polymerized material may be performed using a flowing solvent solution directed toward the plurality of through hole vias (e.g., using a solvent jet procedure) or placing the substrate in a bath containing a solvent solution.

The present disclosure is further directed to a product made by a process that includes providing a substrate having a plurality of through hole vias disposed in the substrate, disposing a monomer material in the plurality of through hole vias, curing the monomer material in-situ and forming a polymer lining, and depositing a conductive material in the plurality of through hole vias. In an aspect, the process for forming the polymer lining of the product includes depositing a coating of the monomer material on the sidewalls of the plurality of through hole vias or depositing a non-crosslinking monomer material to fill the plurality of through hole vias, and removing, after polymerization, a central portion of the polymerized material filling the plurality of through hole vias to provide the polymer lining. In an aspect of the product, the monomer material includes acrylate-based monomers and low-viscosity epoxy-based monomers.

The technical advantages of the present disclosure include, but are not limited to:
(i) providing improved mechanical performance and stability of through hole via interconnects in semiconductor devices by damping and distributing the stress on the vias caused by expansion/shrinkage of a conductive material, e.g., copper, used in forming the interconnects;
(ii) providing for in-situ polymerization of specific monomers to form polymer linings in the through hole vias; and
(iii) providing methods for forming polymer lining in the through hole vias that are compatible with high-volume manufacturing requirements.

To more readily understand and put into practical effect the present devices with through hole via interconnects having polymer linings in the vias and methods for their manufacture, which may provide improved substrates in the devices, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

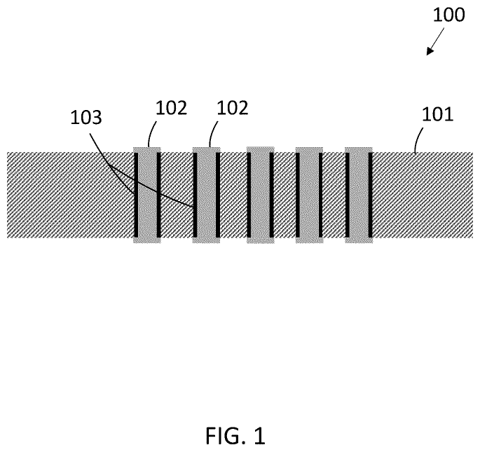

FIG. 1 shows an exemplary representation of a device 100 with a plurality of through hole via interconnects 102 according to an aspect of the present disclosure. In this aspect, the device 100 may have a glass substrate 101, which may be part of a larger glass panel. The through hole via interconnects 102 may be made of a conductive material or metal, such as copper (Cu), that is deposited in through-glass-vias (TGVs) that are coated with polymer linings 103. The through hole via interconnects 102 made of Cu and the glass substrate 101 may have different coefficients of thermal expansion (CTE), which may impart stresses on the glass substrate 101 and lead to device failure. The polymer linings may provide improved mechanical performance and stability of through hole via interconnects in semiconductor devices by damping the stresses on the vias caused by expansion of the through hole via interconnects.

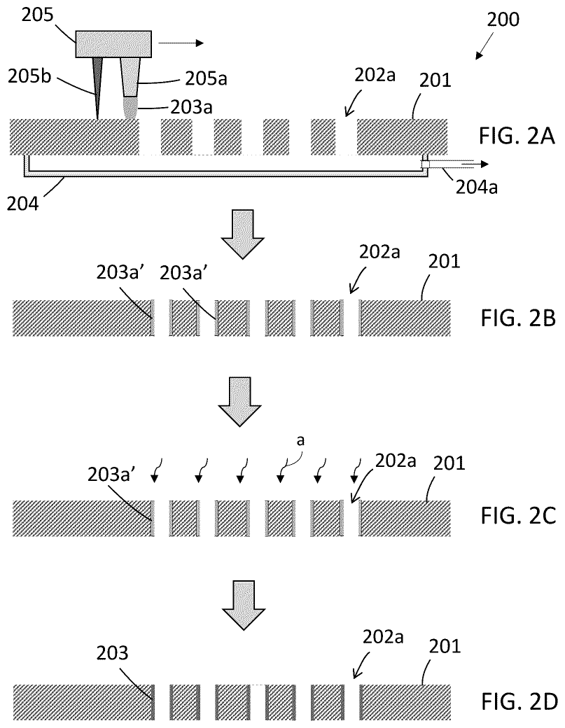

FIGS. 2A through 2D show exemplary representations of the formation of polymer linings 203 for device 200 according to an aspect of the present disclosure. In this aspect, as shown in FIG. 2A, a glass substrate 201 may have a plurality of TGV openings 202a for forming interconnects. A coating tool (not shown) may include a monomer dispenser 205 having a nozzle 205a for dispensing a monomer material 203a that has a low viscosity and surface tension, and a blade 205b for facilitating the distribution of the monomer material 203a into the plurality of TGV openings 202a. It should be understood that, for example, doctor blade coating, spray coating, dip coating, spinning coating, roll coating, and other coating methods may be used in place of the blade coating shown in FIG. 2A.

In an aspect, the glass substrate 201 may be positioned on a support 204 that may be connected by a conduit 204a to a vacuum system (not shown). The application of a vacuum to the backside of the glass substrate 201 may cause the monomer material 203a, which may be selected to have a very viscosity, to flow along the walls of the TGV openings 202a, which may have a surface roughness, to form monomer linings 203a′ as shown in FIG. 2B.

In FIG. 2C, the glass substrate 201 may have the plurality of TGV openings 202a provided with monomer linings 203a′, which may be polymerized/cured/crosslinked using heat or ultraviolet energy “a”, or using other standard polymerization techniques. It should be understood that the process conditions (e.g., time and temperature) for the polymerization of the monomer material will depend on the thickness of the monomer lining 203a′ and the type of monomer material being used. The glass substrate 201 may have the plurality of TGV openings 202a provided with thin polymer linings/coating 203 as shown in FIG. 2D. In an aspect, the thin polymer lining 203 may have a thickness in a range of approximately 50 μ to 500 μm. It may be necessary to provide mechanical polishing of the surfaces of the glass substrate 201 to remove any excess polymer.

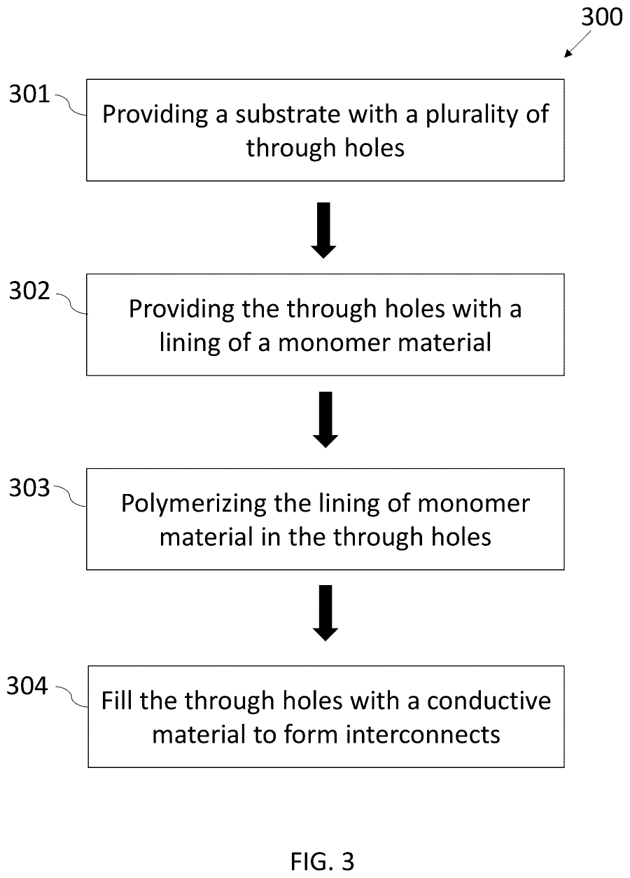

FIG. 3 shows a simplified flow diagram for an exemplary method according to an aspect of the present disclosure.

The operation 301 may be directed to providing a substrate with a plurality of through holes.

The operation 302 may be directed to providing the through holes with a lining of a monomer material.

The operation 303 may be directed to polymerizing the lining of monomer material in the through holes.

The operation 304 may be directed to filling the through holes with a conductive material to form interconnects.

FIGS. 4A through 4E show exemplary representations of another formation of polymer linings 403 for device 400 according to an aspect of the present disclosure. In this aspect, as shown in FIG. 4A, a glass substrate 401 may have a plurality of TGV openings 402a for forming interconnects. A coating tool (not shown) may include a monomer dispenser 405 having a nozzle 405a for dispensing a monomer material 403a that has a low viscosity and surface tension, and a blade 405b for facilitating the distribution of the monomer material 403a into the plurality of TGV openings 402a. It should be understood that, for example, doctor blade coating, spray coating, dip coating, spinning coating, roll coating, and other coating methods may be used in place of the blade coating shown in FIG. 4A.

In an aspect, the monomer dispenser 405 provides the monomer material 403a that flows into and fills the TGV openings 402a to form monomer plugs 403a′ in the glass substrate 401 as shown in FIG. 4B. In this aspect, the viscosity of the monomer material 403a may be higher than the monomer material 203a.

In FIG. 4C, the glass substrate 401 may have the plurality of monomer plugs 403a′, which may be polymerized in the TGVs, i.e., in-situ, using heat or UV energy “a” to form a plurality of polymer plugs 403′. It should be understood that the process conditions (e.g., time and temperature) for the polymerization of the monomer material will depend on the thickness of the monomer plugs 403a′ and the type of monomer material being used. In this aspect, a non-crosslinking polymer should be used when the through holes are to be completely filled with the monomer material so that the central portion is able to be removed after polymerization.

In FIG. 4D, the glass substrate 401 having the plurality of monomer plugs 403′ may be exposed to a solvent “b” that removes central portions of the plurality of polymer plugs 403′. In an aspect, a shower spray or jet may be used to direct the solvent towards the plurality of monomer plugs 403a′. In another aspect, the glass substrate 401 having the plurality of monomer plugs 403′ may be immersed in an agitated solvent bath that circulates solvent towards and removes central portions of the plurality of polymer plugs 403′. Thereafter, the glass substrate 401 may be provided with a plurality of TGV openings 402a with polymer linings 403 as shown in FIG. 4E.

FIG. 5 shows a simplified flow diagram for another exemplary method according to an aspect of the present disclosure.

The operation 501 may be directed to providing a substrate with a plurality of through holes.

The operation 502 may be directed to filling the through holes with a monomer material.

The operation 503 may be directed to polymerizing the monomer material in the through holes.

The operation 504 may be directed to removing a central portion of the polymerized monomer material in the through holes using a solvent.

It will be understood that any property described herein for a particular device with through hole via interconnects having polymer linings in the vias and/or method for forming the polymer linings may also hold for any devices using the present methods described herein. It will also be understood that any property described herein for a specific method may hold for any of the methods described herein. Furthermore, it will be understood that for any device and the methods described herein, not necessarily all the components or operations described will be shown in the accompanying drawings or method, but only some (not all) components or operations may be disclosed.

To more readily understand and put into practical effect the present devices with through hole via interconnects having polymer linings in the vias and present methods for forming the devices having present polymer linings, they will now be described by way of examples. For the sake of brevity, duplicate descriptions of features and properties may be omitted.

### EXAMPLES

Example 1 provides a device including a substrate including a plurality of through hole vias disposed in the substrate, for which each through hole via includes a sidewall, a conductive material filling the plurality of through hole vias, and a polymer lining disposed between the sidewall and the conductive material in each through hole via.

Example 2 may include the device of example 1 and/or any other example disclosed herein, for which the polymer lining includes a polymerized monomer material including low viscosity acrylate-based monomers.

Example 3 may include the device of example 1 and/or any other example disclosed herein, for which the polymer lining includes a polymerized monomer material including low viscosity epoxy-based monomers.

Example 4 may include the device of example 1 and/or any other example disclosed herein, for which the polymer lining has a low modulus of elasticity in a range of approximately one to four gigapascals.

Example 5 may include the device of example 1 and/or any other example disclosed herein, for which the conductive material includes copper.

Example 6 provides a method that includes providing a substrate and forming a plurality of through hole vias disposed in the substrate, disposing a monomer material in the plurality of through hole vias, curing the monomer material and forming a polymer lining, and depositing a conductive material in the plurality of through hole vias.

Example 7 may include the method of example 6 and/or any other example disclosed herein, for which disposing the monomer material in the plurality of through hole vias further includes depositing a coating of the monomer material on sidewalls of the plurality of through hole vias.

Example 8 may include the method of example 6 and/or any other example disclosed herein, for which disposing the monomer material in the plurality of through hole vias further includes depositing the monomer material to fill the plurality of through hole vias and curing the monomer material to form a polymerized material filling the plurality of through hole vias.

Example 9 may include the method of example 8 and/or any other example disclosed herein, further includes removing a central portion of the polymerized material filling the plurality of through hole vias to provide the polymer lining in the through hole vias.

Example 10 may include the method of example 9 and/or any other example disclosed herein, for which removing the central portion of the polymerized material includes using a flowing solvent solution directed toward the plurality of through hole vias.

Example 11 may include the method of example 9 and/or any other example disclosed herein, for which removing the central portion of the polymerized material includes placing the substrate in a bath containing a solvent solution.

Example 12 may include the method of example 6 and/or any other example disclosed herein, for which the curing further includes using ultra-violet energy or heat.

Example 13 may include the method of example 6 and/or any other example disclosed herein, for which curing the monomer material includes forming a polymerized material having a low modulus of elasticity in a range of approximately one-tenth to ten gigapascals to form the polymer lining.

Example 14 provides a product made by a process that includes providing a substrate having a plurality of through hole vias disposed in the substrate, disposing a monomer material in the plurality of through hole vias, curing the monomer material and forming a polymer lining, and depositing a conductive material in the plurality of through hole vias.

Example 15 may include the product of example 14 and/or any other example disclosed herein, for which the process of disposing the monomer material in the plurality of through hole vias further includes depositing a coating of the monomer material on sidewalls of the plurality of through hole vias.

Example 16 may include the product of example 14 and/or any other example disclosed herein, for which the process of disposing the monomer material in the plurality of through hole vias further includes depositing the monomer material to fill the plurality of through hole vias and curing the monomer material forms a polymerized material filling the plurality of through hole vias.

Example 17 may include the product of example 16 and/or any other example disclosed herein, for which the process further includes removing a central portion of the polymerized material filling the plurality of through hole vias to provide the polymer lining in the through hole vias.

Example 18 may include the product of example 14 and/or any other example disclosed herein, for which the monomer material includes acrylate-based monomers.

Example 19 may include the product of example 14 and/or any other example disclosed herein, for which the monomer material includes epoxy-based monomers.
Example 20 may include the product of example 14 and/or any other example disclosed herein, for which the polymer lining has a low modulus of elasticity in a range of approximately one-tenth to ten gigapascals.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words:
coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a substrate comprising a plurality of through hole vias disposed in the substrate, wherein each through hole via comprises a sidewall;
a conductive material filling the plurality of through hole vias; and
a polymer lining disposed between the sidewall and the conductive material in each through hole via.

2. The device of claim 1, wherein the polymer lining comprises a polymerized monomer material comprising low viscosity acrylate-based monomers.

3. The device of claim 1, wherein the polymer lining comprises a polymerized monomer material comprising low viscosity epoxy-based monomers.

4. The device of claim 1, wherein the polymer lining has a low modulus of elasticity in a range of approximately one to four gigapascals.

5. The device of claim 1, wherein the conductive material comprises copper.

6. A method comprising:
providing a substrate and forming a plurality of through hole vias disposed in the substrate;
disposing a monomer material in the plurality of through hole vias;
curing the monomer material and forming a polymer lining; and
depositing a conductive material in the plurality of through hole vias.

7. The method of claim 6, wherein disposing the monomer material in the plurality of through hole vias further comprises depositing a coating of the monomer material on sidewalls of the plurality of through hole vias.

8. The method of claim 6, wherein disposing the monomer material in the plurality of through hole vias further comprises depositing the monomer material to fill the plurality of through hole vias and curing the monomer material to form a polymerized material filling the plurality of through hole vias.

9. The method of claim 8, further comprises removing a central portion of the polymerized material filling the plurality of through hole vias to provide the polymer lining in the through hole vias.

10. The method of claim 9, wherein removing the central portion of the polymerized material comprises using a flowing solvent solution directed toward the plurality of through hole vias.

11. The method of claim 9, wherein removing the central portion of the polymerized material comprises placing the substrate in a bath containing a solvent solution.

12. The method of claim 6, wherein the curing further comprises using ultra-violet energy or heat.

13. The method of claim 6, wherein curing the monomer material comprises forming a polymerized material having a low modulus of elasticity in a range of approximately one-tenth to ten gigapascals to form the polymer lining.

14. A product made by a process comprising:
providing a substrate having a plurality of through hole vias disposed in the substrate;
disposing a monomer material in the plurality of through hole vias;
curing the monomer material and forming a polymer lining; and
depositing a conductive material in the plurality of through hole vias.

15. The product of claim 14, wherein the process of disposing the monomer material in the plurality of through hole vias further comprises depositing a coating of the monomer material on sidewalls of the plurality of through hole vias.

16. The product of claim 14, wherein the process of disposing the monomer material in the plurality of through hole vias further comprises depositing the monomer material to fill the plurality of through hole vias and curing the monomer material forms a polymerized material filling the plurality of through hole vias.

17. The product of claim 16, wherein the process further comprises removing a central portion of the polymerized material filling the plurality of through hole vias to provide the polymer lining in the through hole vias.

18. The product of claim 14, wherein the monomer material comprises acrylate-based monomers.

19. The product of claim 14, wherein the monomer material comprises low-viscosity epoxy-based monomers.

20. The product of claim 14, wherein the polymer lining has a low modulus of elasticity in a range of approximately one-tenth to ten gigapascals.
